(19) United States
(12) Patent Application Publication
(10) Pub. No.: US 2024/0381550 A1
(43) Pub. Date: Nov. 14, 2024

(54) MOUNTING DEVICE

(71) Applicant: Ocean Vision Environmental Research Pty Ltd, Bayswater (AU)

(72) Inventors: Matthew HARVEY, Kardinya (AU); Nicholas DOBSON, Mont Albert North (AU)

(73) Assignee: Ocean Vision Environmental Research Pty Ltd, Bayswater (AU)

(21) Appl. No.: 18/652,544

(22) Filed: May 1, 2024

(30) Foreign Application Priority Data
May 10, 2023 (AU) AU2023901410

(51) Int. Cl. H05K 5/02; H01R 12/71

(52) U.S. Cl. CPC H05K 5/0217; H01R 12/71; H05K 5/0247

(57) ABSTRACT

A mounting device for mounting at least one item relative to internal surfaces of a case is disclosed. The mounting device has spaced first and second legs, each of the first and second legs having a free end, and a cross member extending between the first and second legs, the cross member formed of resilient material and including at least one slot for receiving an item, and the slot having a slot width. Movement of the first and second free ends of the respective first and second legs towards each other causes flexure of the cross member and a reduction in the slot width.

### FIELD OF THE INVENTION

The present invention relates to a mounting device for mounting an item such as component board, for example a PCB board, to an internal wall of a case.

### BACKGROUND OF THE INVENTION

It is known to mount a component board to an internal surface of a component board case by providing oppositely disposed slots formed in the internal surface of the case, each opposite pair of slots slidably receiving a component board.

However, providing such slots in the internal surface of the case increases production costs, particularly if a continuous smooth surface is required for waterproof sealing purposes at the open end(s) of the case. Providing dedicated internal slots also restricts flexibility in terms of the number and type of component boards that can be received in the case.

### SUMMARY OF THE INVENTION

In accordance with a first aspect of the present invention, there is provided a mounting device for mounting at least one item relative to internal surfaces of a case, the mounting device comprising:
spaced first and second legs, each of the first and second legs having a free end; and
a cross member extending between the first and second legs, the cross member formed of resilient material and including at least one slot for receiving an item, the slot having a slot width;
wherein movement of the first and second free ends of the respective first and second legs towards each other causes flexure of the cross member and a reduction in the slot width.

In an embodiment, the mounting device comprises a C-shaped member including a base member and the first and second legs, the first and second legs extending from respective opposite longitudinal ends of the base member. The C-shaped member may be formed of resilient material.

In an embodiment, each of the first and second legs has a first outwardly extending protruding portion located relatively adjacent the base member, wherein the distance between the first protruding portions is such that the first protruding portions come into contact with the internal surfaces of the case when the mounting device is received in the case and the base member flexes to frictionally engage with the internal surfaces of the case.

In an embodiment, the base member includes a reduced thickness portion that functions to promote flexibility.

In an embodiment, each of the first and second legs has a second outwardly extending protruding portion located at a free end of the leg relatively remote from the base member.

In an embodiment, the distance between outwardly facing surfaces of the second protruding portions is larger than the distance between outwardly facing surfaces of the first protruding portions to ensure that the cross member flexes in a manner that causes the width of the slot to reduce when the mounting device is received in the case.

In an embodiment, each slot is configured so that the item is receivable in the slot with sufficient friction to loosely retain the item relative to the cross member but sufficiently low friction to enable the item to be readily disengaged from the slot by a user.

In an embodiment, the slot includes a first engagement portion and the item includes a second engagement portion, the first and second engagement portions having complementary shapes such that the first engagement portion mates with the second engagement portion and loosely retains the item relative to the cross member when the item is received in the slot. One of the first and second engagement portions may include at least one notch and the other of the first and second engagement portions may include at least one complementary projection.

In an embodiment, the cross member includes a plurality of slots.

In an embodiment, the cross member is integrally formed with the first and second legs.

In an embodiment, at least part of the mounting device is formed of fibreglass filled nylon material.

In an embodiment, the mounting device includes an earthing connection arranged to electrically connect to the case and to an earthing connection on an item when the mounting device is connected to the item and the mounting device is received in the case.

In an embodiment, the mounting device includes at least one electrical connector arranged to define an electrical connection between at least 2 component boards when the mounting device is connected to the component boards and the mounting device is received in the case.

### BRIEF DESCRIPTION OF THE DRAWINGS

The present invention will now be described, by way of example only, with reference to the accompanying drawings, in which:

FIG. 1 is a diagrammatic perspective view of a component case and component board module received in the case and engaged with internal surfaces of the case;

FIG. 2 is a diagrammatic perspective view of a mounting device in accordance with an embodiment of the present invention;

FIG. 3 is a diagrammatic end view of the component board module shown in FIG. 1;

FIG. 4 is a diagrammatic perspective view of the component board module shown in FIG. 3; and

FIG. 5 is a diagrammatic perspective view of the component case shown in FIG. 1 with the component board module shown during insertion of the component board module into the component case.

### DESCRIPTION OF AN EMBODIMENT OF THE INVENTION

An embodiment of a mounting device will now be described in relation to mounting of a component board, such as a PCB board, relative to a case, although it will be understood that the mounting device may be used to mount other items relative to a case, such as trays.

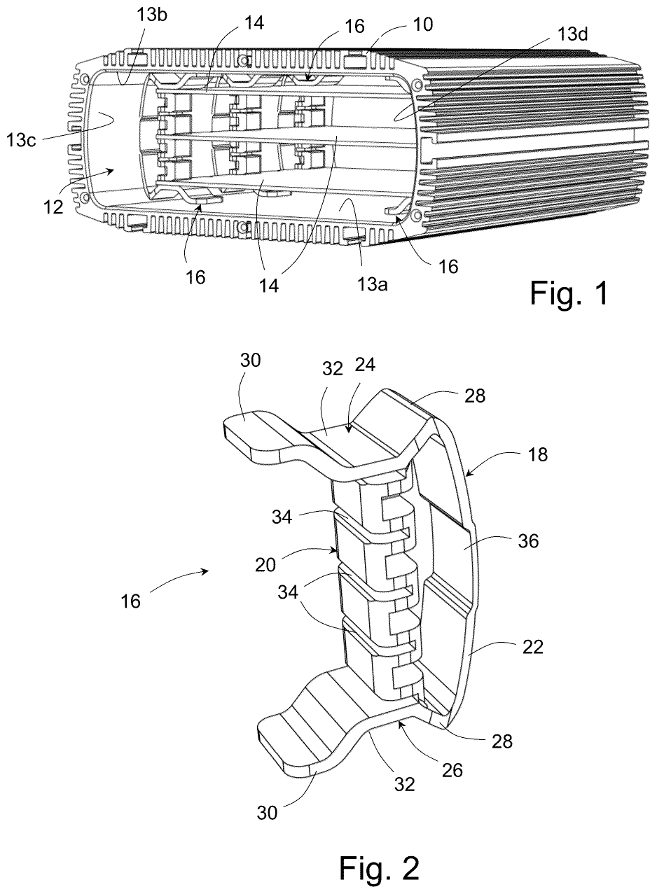

Referring to the drawings, FIG. 1 shows a component case 10 for receiving at least one component board, such as at least one PCB board. In the present example, the case 10 is open at 2 opposite ends, although it will be understood that a case open at only one end is envisaged. The case 10 includes a continuous smooth internal surface between the open ends that facilitates a radial seal between the case and an end panel (not shown).

The internal surface defines bottom and top internal surface portions 13a and 13b, and first and second side surface portions 13c, 13d, as shown in FIG. 1.

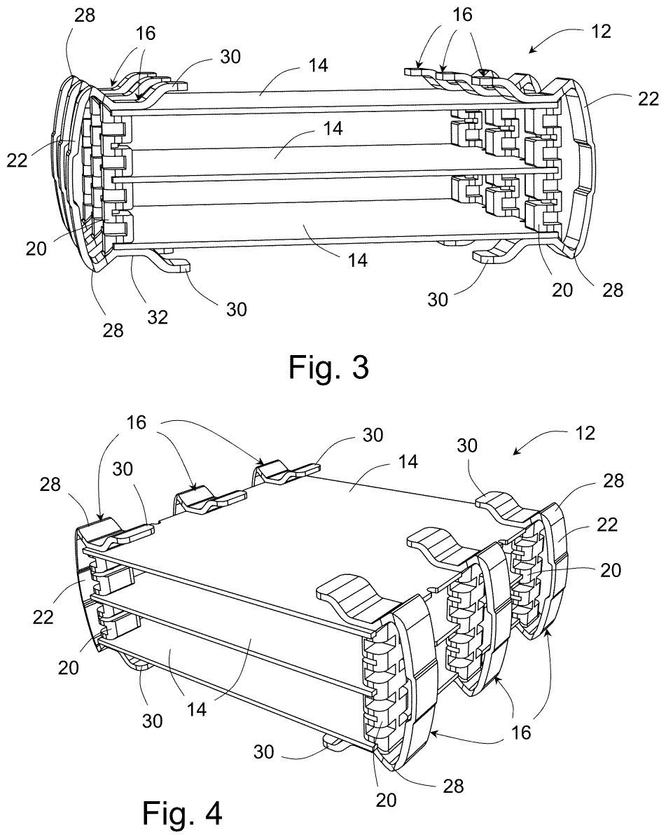

As shown in FIG. 1, the case 10 receives a component board module 12, shown more particularly in FIGS. 3 and 4.

The component board module 12 includes at least one component board 14 engaged with a plurality of mounting devices 16, shown more particularly in FIG. 2. As discussed in more detail below, the component board module 12 in this example includes several component board(s) 14, and the configuration of the mounting device 16 is such that when the component board module 12 is received in the case 10, the mounting devices 16 frictionally engage with internal surface portions of the case 10 and a clamping force exerted on the component board(s) 14 by the mounting devices 16 increases. In this example, the mounting device 16 engages with bottom and top internal surface portions 13a, 13b of the case 10, although it will be understood that the mounting device 16 may be configured to engage with other internal surface portions of the case 10.

Referring to FIG. 2, an example mounting device 16 is shown that includes a generally C-shaped member 18 and a cross member 20, in this example that is integrally formed with the C-shaped member 18. The C-shaped member 18 includes a base member 22 and first and second legs 24, 26 that extend from respective opposite longitudinal ends of the base member 22. Each of the first and second legs 24, 26 has a first protruding portion 28 located relatively adjacent the base member 22 and a second protruding portion 30 located at a free end of the leg relatively remote from the base member 22. Between each pair of first and second protruding portions 28, 30 is a trough portion 32. As shown in FIG. 2, the first and second protruding portions 28, 30 extend outwardly of the mounting device 16 such that the first and second protruding portions 28, 30 come into contact with bottom and top internal surface portions 13a, 13b of the case 10 when the component board module 12 is received in the case 10.

The cross member 20 includes at least one slot 34, in this example 5 slots 34, each of which is configured to receive an item, in this example a component board 14, as shown for example in FIGS. 3 to 5. Each slot 34 is configured so that the component board 14 is receivable in the slot 34 with sufficient friction to loosely retain the component board 14 relative to the cross member 20 but sufficiently low friction to enable the component board 14 to be readily disengaged from the slot 34 by a user. For example, the slot may include a first engagement portion and the item may include a second engagement portion, the first and second engagement portions having complementary shapes such that the first engagement portion mates with the second engagement portion and loosely retains the item relative to the cross member when the item is received in the slot. One of the first and second engagement portions may include at least one notch and the other of the first and second engagement portions may include at least one complementary projection.

In this example, the base member 22 of the C-shaped member 18 is configured so as to flex when the mounting device 16 is disposed in the case 10 and the first and second protruding portions 28, 30 contact the bottom and top internal surface portions 13a, 13b of the case 10, for example by forming the base member 22 of resilient material, ensuring that the distance between outwardly facing surfaces of the first protruding portions 28 is slightly larger than the width of the internal space defined by the bottom and top internal surface portions 13a, 13b of the component case 10, and providing the base member 22 with a reduced thickness portion 36 that functions to promote flexibility.

In addition, when the mounting device 16 is disposed in the case 10 and the first and second protruding portions 28, 30 contact the top and bottom internal surface portions 13a, 13b of the case 10, the second protruding portions 30 at the free ends of the first and second leg portions 24, 26 move towards each other because the distance between outwardly facing surfaces of the second protruding portions 30 is slightly larger than the width of the internal space defined by the internal surface portions 13a, 13b of the component case 10. This causes the cross member 20 to flex in a way that causes the slots 34 to slightly reduce in size, and therefore during use a clamping force exerted by the slots 34 on a received component board 14 increases when the component mounting board 14 is received in the case 10. Each leg portion 24, 26 effectively operates as a hinge that rotates relative to the point of contact between the first protruding portion 28 and the inside surface 13 of the case 10 as the mounting device 16 is inserted into the case 10.

In order to ensure that the cross member 20 flexes in a manner that causes the width of the slots 34 to reduce when the mounting device 16 is received in the case 10, the distance between outwardly facing surfaces of the second protruding portions 30 may be slightly larger than the distance between outwardly facing surfaces of the first protruding portions 28.

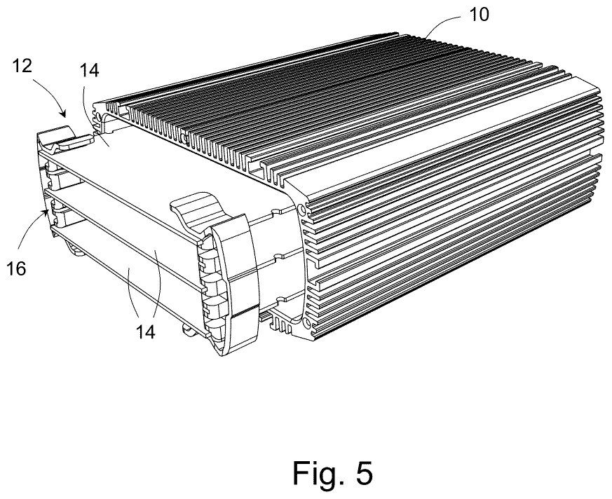

In operation, a user first disposes one or more component boards 14, such as one or more PCB boards, between corresponding opposite facing slots 34 of several pairs of mounting devices 16 to form a component board module 12, as shown in FIGS. 3 and 4, then slides the component board module 12 into the case 10, as shown in FIG. 5. As each mounting device 16 is received in the case 10, the mounting device 16 is caused to flex such that the first and second protruding portions 28, 30 move slightly towards each other, thereby causing the mounting device 16 to frictionally engage with the internal surface portions 13a, 13b of the case 10 and the clamping force exerted by the slots 34 on the received components board(s) 14 to increase.

In the present example, the mounting device 16 is formed of fibreglass filled nylon material, although it will be understood that any suitable resilient material is envisaged.

While the present embodiment is described in relation to a mounting device 16 configured to engage with one side of an item, it will be understood that other types of mounting device 16 are envisaged. For example, an alternative mounting device (not shown) may be configured as a corner mounting device arranged to engage with 2 adjacent sides of an item.

In a variation, the mounting device 16 may include an earthing connection arranged to electrically connect to the case and to an earthing connection on a component board 14 when the mounting device 16 is connected to the component board 14.

The mounting device may also include at least one electrical connector that defines an electrical connection between at least 2 component boards when the mounting device is connected to the component boards and the mounting device is received in the case.

It will be appreciated that the present mounting device operates so as to both frictionally engage with a case and increase a clamping force on a retained item when the mounting device resiliently flexes in response to insertion of the mounting device into the case.

It will be understood that since the present mounting devices 16 enable one or more items, such as one or more component boards 14, to be retained in position relative to a smooth continuous internal surface of a case 10 without the need to provide slots in the internal surface of the case 10, the risk of compromising a waterproof seal at the open end(s) of the case is avoided.

It will also be appreciated that since the component board capacity of a component case 10 is determined by the number of slots 34 and the spacing between the slots 34 in the mounting devices 16, it is possible to tailor the component board capacity of the case simply by producing different mounting devices 16 with different numbers of slots 34 and different slot spacings, and selecting an appropriate set of mounting devices 16.

In the claims that follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

It is to be understood that, if any prior art publication is referred to herein, such reference does not constitute an admission that the publication forms a part of the common general knowledge in the art, in Australia or any other country.

Modifications and variations as would be apparent to a skilled addressee are deemed to be within the scope of the present invention.

1. A mounting device for mounting at least one item relative to internal surfaces of a case, the mounting device comprising:
spaced first and second legs, each of the first and second legs having a free end; and
a cross member extending between the first and second legs, the cross member formed of resilient material and including at least one slot for receiving an item, the slot having a slot width;
wherein movement of the first and second free ends of the respective first and second legs towards each other causes flexure of the cross member and a reduction in the slot width.

2. A mounting device as claimed in claim 1, comprising a C-shaped member including a base member and the first and second legs, the first and second legs extending from respective opposite longitudinal ends of the base member.

3. A mounting device as claimed in claim 2, wherein each of the first and second legs has a first outwardly extending protruding portion located relatively adjacent the base member, wherein the distance between the first protruding portions is such that the first protruding portions come into contact with the internal surfaces of the case when the mounting device is received in the case and the base member flexes to frictionally engage with the internal surfaces of the case.

4. A mounting device as claimed in claim 3, wherein the base member includes a reduced thickness portion that functions to promote flexibility.

5. A mounting device as claimed in claim 3, wherein each of the first and second legs has a second outwardly extending protruding portion located at a free end of the leg relatively remote from the base member.

6. A mounting device as claimed in claim 5, wherein the distance between outwardly facing surfaces of the second protruding portions is larger than the distance between outwardly facing surfaces of the first protruding portions to ensure that the cross member flexes in a manner that causes the width of the slot to reduce when the mounting device is received in the case.

7. A mounting device as claimed in claim 1, wherein each slot is configured so that the item is receivable in the slot with sufficient friction to loosely retain the item relative to the cross member but sufficiently low friction to enable the item to be readily disengaged from the slot by a user when the mounting device is not received in the case.

8. A mounting device as claimed in claim 7, wherein the slot includes a first engagement portion and the item includes a second engagement portion, the first and second engagement portions having complementary shapes such that the first engagement portion mates with the second engagement portion and loosely retains the item relative to the cross member when the item is received in the slot.

9. A mounting device as claimed in claim 8, wherein one of the first and second engagement portions includes at least one notch and the other of the first and second engagement portions includes at least one complementary projection.

10. A mounting device as claimed in claim 1, wherein the cross member includes a plurality of slots.

11. A mounting device as claimed in claim 1, wherein the cross member is integrally formed with the first and second legs.

12. A mounting device as claimed in claim 1, wherein at least part of the mounting device is formed of fibreglass filled nylon material.

13. A mounting device as claimed in claim 1, wherein the mounting device is configured to engage with two adjacent sides of the item, with an opposite pair of internal surfaces of the case, and with a case end panel disposed during use adjacent the opposite pair of internal surfaces.

14. A mounting device as claimed in claim 1, wherein the mounting device includes an earthing connection arranged to electrically connect to the case and to an earthing connection on an item when the mounting device is connected to the item and the mounting device is received in the case.

15. A mounting device as claimed in claim 1, wherein the mounting device includes at least one electrical connector arranged to define an electrical connection between at least 2 component boards when the mounting device is connected to the component boards and the mounting device is received in the case.
